(19) United States
(12) Patent Application Publication
(10) Pub. No.: US 2025/0392274 A1
(43) Pub. Date: Dec. 25, 2025

(54) TWO-STAGE OPERATIONAL AMPLIFIER AND OPTICAL SENSOR

(71) Applicant: LITE-ON SINGAPORE PTE. LTD., Singapore (SG)

(72) Inventor: Yoshio Nishida, Singapore (SG)

(21) Appl. No.: 19/206,063

(22) Filed: May 13, 2025

(30) Foreign Application Priority Data
Jun. 19, 2024 (SG) 10202401790T

(51) Int. Cl. H03F 3/45

(52) U.S. Cl. CPC H03F 3/45475; H03F 2200/264

(57) ABSTRACT

An optical sensor at least includes a two-stage operational amplifier and a photo diode. The two-stage operational amplifier includes a first amplifier, a second amplifier and a compensation circuit. Input terminals of the second amplifier are respectively connected to output terminals of the first amplifier. The compensation circuit is connected to the plurality of input terminals of the second amplifier. The compensation circuit can provide different compensated voltage depending on whether the first amplifier received input voltage outputted from a load or not.

### CROSS-REFERENCE TO RELATED PATENT APPLICATION

This application claims the benefit of priority to Singapore Patent Application No. 10202401790T, filed on Jun. 19, 2024. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to an operational amplifier, and more particularly to a two-stage operational amplifier and an optical sensor.

### BACKGROUND OF THE DISCLOSURE

The operational amplifier (op-amp) constituting a current integrator is a key circuit block in optical sensors. The op-amp exhibits two different bandwidths (meaning, circuit speed) in two load conditions that are a loading state and a no-loading state. Therefore, there is a challenge to secure high-speed and stability for the two load conditions.

### SUMMARY OF THE DISCLOSURE

In response to the above-referenced technical inadequacies, the present disclosure provides a two-stage operational amplifier. The two-stage operational amplifier includes a first amplifier, a second amplifier and a compensation circuit. A plurality of input terminals of the first amplifier are respectively coupled to a plurality of input voltages. A plurality of input terminals of the second amplifier are respectively connected to a plurality of output terminals of the first amplifier. The compensation circuit is connected to the plurality of input terminals of the second amplifier. The compensation circuit can provide different compensated voltage depending on whether the input voltage is outputted from a load or not. When the input voltage received by one of the plurality of input terminals of the first amplifier is outputted from a load, the compensation circuit compensates a first voltage received by the compensation circuit to form a first compensation voltage based on a first compensation value. When the input voltage received by one of the plurality of input terminals of the first amplifier is not outputted from the load, the compensation circuit compensates a second voltage received by the compensation circuit to form a second compensation voltage based on a second compensation value.

In order to solve the above-mentioned problems, one of the technical aspects adopted by the present disclosure is to provide an optical sensor. The optical sensor includes a current integrator, a photodiode and a load switch. The current integrator includes a two-stage operational amplifier. The two-stage operational amplifier includes a first amplifier, a second amplifier and a compensation circuit. A plurality of input terminals of the first amplifier are respectively coupled to a plurality of input voltages. A plurality of input terminals of the second amplifier are respectively connected to a plurality of output terminals of the first amplifier. The compensation circuit is connected to one or more of the plurality of input terminals of the second amplifier. An anode of the photodiode is grounded. The load switch is connected between a cathode of the photodiode and the one of the plurality of input terminals of the first amplifier. When the input voltage received by the one of the plurality of input terminals of the first amplifier is outputted from a load, the compensation circuit compensates a first voltage received by the compensation circuit to form a first compensation voltage based on a first compensation value. When the input voltage received by the one of the plurality of input terminals of the first amplifier is not outputted from the load, the compensation circuit compensates a second voltage received by the compensation circuit to form a second compensation voltage based on a second compensation value.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a circuit diagram of a two-stage operational amplifier according to a first embodiment of the present disclosure;

FIG. 2 is a circuit diagram of a two-stage operational amplifier according to a second embodiment of the present disclosure;

FIG. 3 is a circuit diagram of a two-stage operational amplifier according to a third embodiment of the present disclosure;

FIG. 4 is a circuit diagram of a two-stage operational amplifier according to a fourth embodiment of the present disclosure;

FIG. 5 is a circuit diagram of a two-stage operational amplifier according to a fifth embodiment of the present disclosure;

FIG. 6 is a circuit diagram of an optical sensor including the two-stage operational amplifier according to the first to fifth embodiments of the present disclosure;

FIG. 7 is a waveform diagram of signals of the two-stage operational amplifier of the first to fifth embodiments of the present disclosure and a conventional operational amplifier; and

FIG. 8 is a waveform diagram of signals of the two-stage operational amplifier according to the first to fifth embodiments of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, voltages or the like, which are for distinguishing one component/voltage from another one only, and are not intended to, nor should be construed to impose any substantive limitations on the components, voltages or the like.

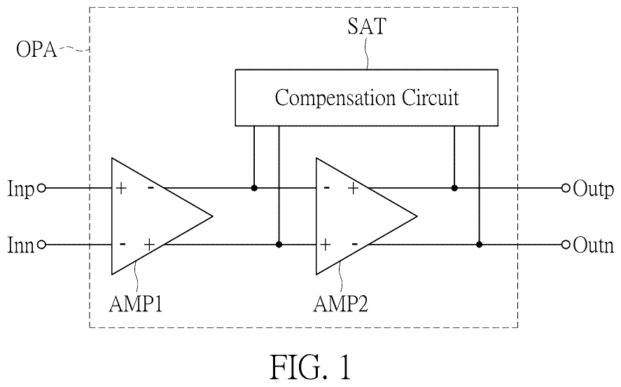

As shown in FIG. 1, a two-stage operational amplifier OPA of a first embodiment includes two amplifiers that are a first amplifier AMP1 and a second amplifier AMP2 connected in series, and a compensation circuit SAT.

The first amplifier AMP1 includes a plurality of input terminals, wherein the plurality of input terminals of the first amplifier AMP1 includes a first input terminal such as a non-inverting input terminal, and a second input terminal such as an inverting input terminal.

The non-inverting input terminal of the first amplifier AMP1 is used as a first input terminal Inp of the two-stage operational amplifier OPA.

The non-inverting input terminal of the first amplifier AMP1 is used as a second input terminal Inn of the two-stage operational amplifier OPA.

The first amplifier AMP1 further includes a plurality of output terminals. The plurality of output terminals of the first amplifier AMP1 includes a first output terminal such as a negative output terminal, and a second output terminal such as a positive output terminal.

The plurality of input terminals of the first amplifier AMP1 are respectively coupled to a plurality of input voltages. The first amplifier AMP1 is used for increasing a difference between the input voltages, especially on that of the first input terminal Inp and the second input terminal Inn, and a voltage of a reverse phase is output by the second amplifier AMP2.

The second amplifier AMP2 includes a plurality of input terminals. The plurality of input terminals of the second amplifier AMP2 includes a first input terminal such as an inverting input terminal, and a second input terminal such as a non-inverting input terminal. The plurality of input terminals of the second amplifier AMP2 are respectively connected to a plurality of output terminals of the first amplifier AMP1. The inverting input terminal of the second amplifier AMP2 is connected to the negative output terminal of the first amplifier AMP1, and the non-inverting input terminal of the second amplifier AMP2 is connected to the positive output terminal of the first amplifier AMP1.

The second amplifier AMP2 further includes a plurality of output terminals. The plurality of output terminals of the second amplifier AMP2 may include a first output terminal such as a positive output terminal, and a second output terminal such as a negative output terminal.

The positive output terminal of the second amplifier AMP2 is used as a first output terminal Outp such as a positive output terminal of the two-stage operational amplifier OPA.

The negative output terminal of the second amplifier AMP2 is used as a second output terminal Outn such as a negative output terminal of the two- stage operational amplifier OPA.

The second amplifier AMP2 amplifies a difference of a reverse phase voltage received by the first amplifier AMP1, and outputs the reverse phase output voltage of the first output terminal Outp and the second output terminal Outn. A gain of the first amplifier AMP1 is high, an output amplitude of the second amplifier AMP2 is large, and a gain of the two-stage operational amplifier OPA is large, and an amplitude of a signal operated by the two-stage operational amplifier OPA is large.

The compensation circuit SAT is connected between the inverting input terminal of the second amplifier AMP2 and the positive output terminal of the second amplifier AMP2.

The compensation circuit SAT is connected between the non-inverting input terminal of the second amplifier AMP2 and the negative output terminal of the second amplifier AMP2.

It is worth noting that, when the input voltage received by the inverting input terminal of the second amplifier AMP2 is outputted from a load, the compensation circuit SAT compensates a first voltage to form a first compensation voltage based on a first compensation value.

It is worth noting that, when the input voltage received by the inverting input terminal of the second amplifier AMP2 is not outputted from the load, the compensation circuit SAT compensates a second voltage to form a second compensation voltage based on a second compensation value. The second compensation value is different from the first compensation value.

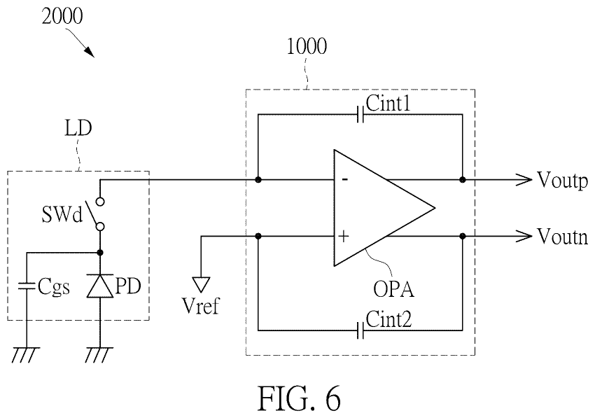

The two-stage operational amplifier OPA shown in FIG. 1 to FIG. 5 is suitable for many applications, such as an optical sensor 2000 shown in FIG. 6. The optical sensor 2000 includes a current integrator 1000 and a load circuit LD. The current integrator 1000 includes a first integrating capacitor Cint1, a second integrating capacitor Cint2 and the two-stage operational amplifier OPA shown in FIG. 1 to FIG. 5. The load circuit LD includes a load switch SWd and the load that are connected in series. The load includes a photodiode PD and a capacitor Cgs that are connected in parallel, where a capacitance of the capacitor Cgs is an upper limit value of a capacitance of the photodiode PD and limit an overall capacitance to be not larger a predetermined threshold. Thus, the parallel capacitor Cgs helps to smooth out these current variations. This reduces noise and interference, thereby improving quality of the signal.

An anode of the photodiode PD is grounded. The load switch SWd is connected to a first input terminal such as an inverting input terminal of the operational amplifier OPA and a node between a cathode of the photodiode PD and the capacitor Cgs. The load switch SWd is turned on or off by an external control circuit (not shown in drawing). Two terminals of the first integrating capacitor Cint1 are respectively coupled to the inverting input terminal and the positive output terminal Voutp of the operational amplifier OPA. A second input terminal such as a non-inverting input terminal of the operational amplifier OPA receives a reference voltage Vref. Two terminals of the second integrating capacitor Cint2 are respectively coupled to the non-inverting input terminal and the negative output terminal Voutn of the operational amplifier OPA.

The photodiode PD converts energy of light irradiated on the photodiode PD into a photocurrent. The photocurrent flows from the photodiode PD through the load switch SWd being turned on into the inverting input terminal of the operational amplifier OPA shown in FIG. 6. Then, the photocurrent flows to one of the plurality of input terminals of the first amplifier AMP1 inside the operational amplifier OPA as shown in FIG. 1 to FIG. 5.

When the load switch SWd is turned on, the input voltage received by the one of the plurality of input terminals of the first amplifier AMP1 is outputted from the photodiode PD. At this time, the compensation circuit SAT compensates the first voltage received by the compensation circuit SAT to form the first compensation voltage based on the first compensation value.

In contrast, when the load switch SWd is turned off, the inverting input terminal of the operational amplifier OPA is unconnected to the cathode of the photodiode PD. At this time, the photocurrent generated by the photodiode PD does not flow to the inverting input terminal of the operational amplifier OPA through the load switch SWd. Under this condition, the compensation circuit SAT compensates the second voltage received by the compensation circuit SAT to form the second compensation voltage based on the second compensation value.

It is worth noting that, when the current integrator 1000 is unconnected to the load circuit LD, the current integrator 1000 has lower stability. Therefore, under this condition, the voltage of the current integrator 1000 is compensated based on the second compensation value being larger than the first compensation value.

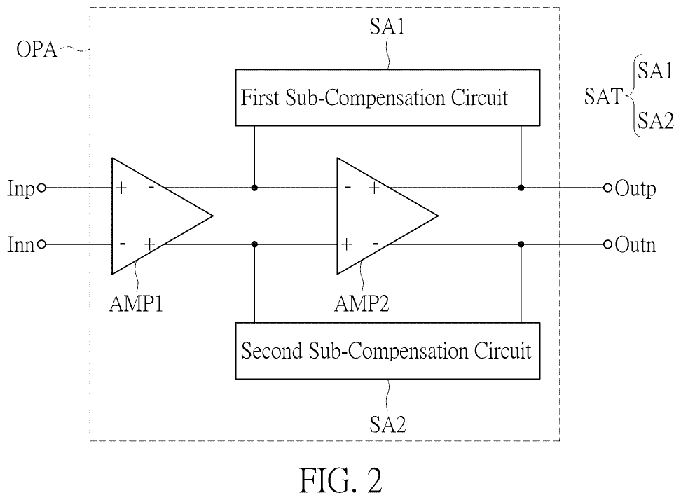

Reference is made to FIG. 2, which is a circuit diagram of a two-stage operational amplifier according to the second embodiment.

As shown in FIG. 2, the two-stage operational amplifier OPA includes the first amplifier AMP1, a second amplifier AMP2 and the compensation circuit SAT. The compensation circuit SAT includes a plurality of sub-compensation circuits such as a first sub-compensation circuit SA1 and a second sub-compensation circuit SA2.

Each of the plurality of sub-compensation circuits has a first terminal and a second terminal. The first terminals of the plurality of sub-compensation circuits of the two-stage operational amplifier OPA are respectively connected to the plurality of input terminals of the second amplifier AMP2. For example, as shown in FIG. 2, the first terminal of the first sub-compensation circuit SA1 is connected to the inverting input terminal of the second amplifier AMP2, and the first terminal of the second sub-compensation circuit SA2 is connected to the non-inverting input terminal of the second amplifier AMP2.

The second terminals of the plurality of sub-compensation circuits of the two-stage operational amplifier OPA are respectively connected to the plurality of output terminals of the second amplifier AMP2. For example, as shown in FIG. 2, the second terminal of the first sub-compensation circuit SA1 is connected to the positive output terminal of the second amplifier AMP2, and the second terminal of the second sub-compensation circuit SA2 is connected to the negative output terminal of the second amplifier AMP2.

When the input voltage received by one of the plurality of input terminals of the first amplifier AMP1 is outputted from the load, the voltage between the inverting input terminal and the positive output terminal of the second amplifier AMP2 is compensated by the first sub-compensation circuit SA1 based on the first compensation value. At the same time, the voltage between the non-inverting input terminal and the negative output terminal of the second amplifier AMP2 is compensated by the compensation circuit SA2 based on the first compensation value.

Conversely, when the input voltage received by one of the plurality of input terminals of the first amplifier AMP1 is not outputted from the load, the voltage between the inverting input terminal and the positive output terminal of the second amplifier AMP2 is compensated by the first sub-compensation circuit SA1 based on the second compensation value. At the same time, the voltage between the non-inverting input terminal and the negative output terminal of the second amplifier AMP2 is compensated by the compensation circuit SA2 based on the second compensation value.

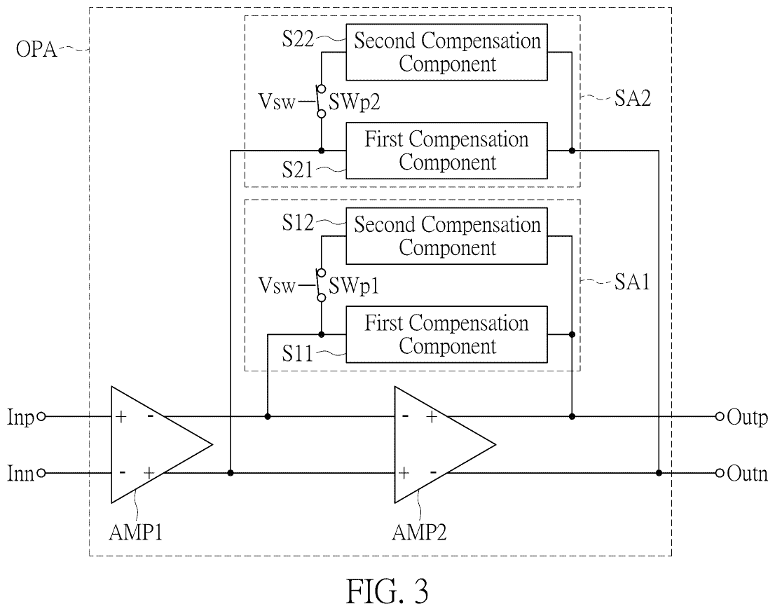

Reference is made to FIG. 3, in the third embodiment, the first sub-compensation circuit SA1 includes a compensation switch SWp1, a first compensation component S11 and a second compensation component S12, and the second sub-compensation circuit SA2 includes a compensation switch SWp2, a first compensation component S21 and a second compensation component S22. The second compensation components S12, S22 are respectively connected to the first compensation components S11, S21 in parallel.

A first terminal of the compensation switch SWp1 is connected to the inverting input terminal of the second amplifier AMP2. A control terminal of the compensation switch SWp1 is coupled to a variable control voltage Vsw, or is connected to an external control circuit (not shown in drawing) and receives the variable control voltage Vsw from the external control circuit.

A first terminal of the first compensation component S11 is connected to the inverting input terminal of the second amplifier AMP2. A second terminal of the first compensation component S11 is connected to the positive output terminal of the second amplifier AMP2.

A first terminal of the second compensation component S12 is connected to a second terminal of the compensation switch SWp1. A second terminal of the second compensation component S12 is connected to the positive output terminal of the second amplifier AMP2.

On the other hand, a first terminal of the compensation switch SWp2 is connected to the non-inverting input terminal of the second amplifier AMP2. A control terminal of the compensation switch SWp2 is coupled to the variable control voltage Vsw, or is connected to the external control circuit and receives the variable control voltage Vsw from the external control circuit.

A first terminal of the first compensation component S21 is connected to the non-inverting input terminal of the second amplifier AMP2. A second terminal of the first compensation component S21 is connected to the negative output terminal of the second amplifier AMP2.

A first terminal of the second compensation component S22 is connected to a second terminal of the compensation switch SWp2. A second terminal of the second compensation component S22 is connected to the negative output terminal of the second amplifier AMP2.

When the load switch SWd shown in FIG. 6 is turned on, the inverting input terminal of the current integrator 1000 is connected to the load such as the photodiode PD through the load switch SWd in the optical sensor 2000 shown in FIG. 6, the compensation switch SWp1 and the compensation switch SWp2 as shown in FIG. 3 are turned off by the variable control voltage Vsw at an initial voltage level such as a low voltage level.

Thus, the voltage between the inverting input terminal and the positive output terminal of the second amplifier AMP2 is compensated based on the first compensation value by the first compensation component S11, and the voltage between the non-inverting input terminal and the negative output terminal of the second amplifier AMP2 is compensated based on the first compensation value by the first compensation component S21.

Conversely, when the load switch SWd is turned off, the inverting input terminal of the current integrator 1000 is unconnected to the photodiode PD in the optical sensor 2000 shown in FIG. 6, the compensation switch SWp1 and the compensation switch SWp2 shown in FIG. 3 are turned on by the variable control voltage Vsw at a first voltage level such as a high voltage level.

Thus, the voltage between the inverting input terminal and the positive output terminal of the second amplifier AMP2 is compensated based on the second compensation value by the first compensation component S11 and the second compensation component S12, and the voltage between the non- inverting input terminal and the negative output terminal of the second amplifier AMP2 is compensated based on the second compensation value by the first compensation component S21 and the second compensation component S22.

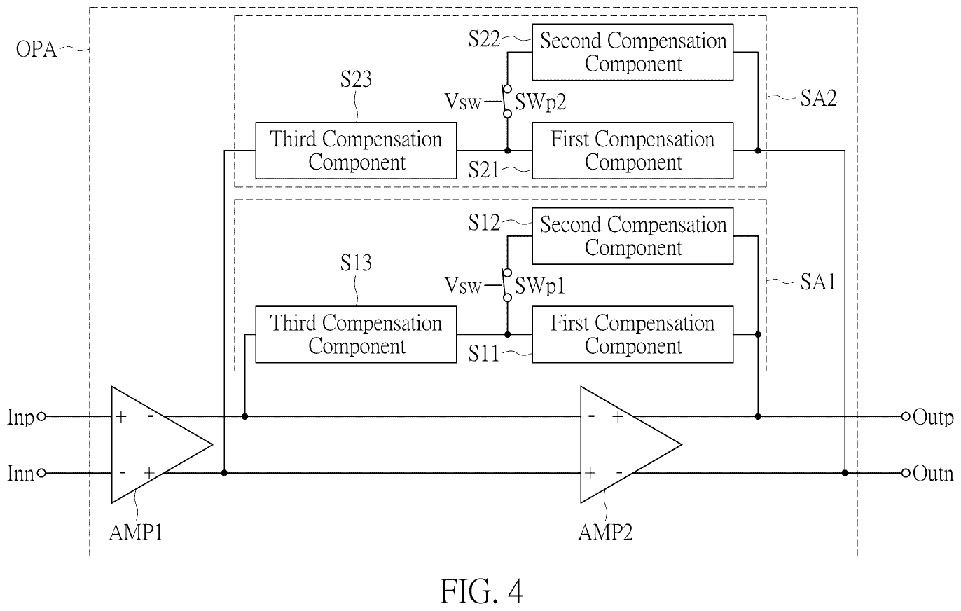

Reference is made to FIG. 4, which is a circuit diagram of a two-stage operational amplifier according to the fourth embodiment. The descriptions of the fourth embodiment that are the same as the descriptions of the third embodiment are not repeated herein.

One difference between the fourth and third embodiments is that, the first sub-compensation circuit SA1 further includes a third compensation component S13 that is connected between the inverting input terminal of the second amplifier AMP2 and is connected to a node to which the first terminal of the first compensation component S11 and the first terminal of the compensation switch SWp1 are connected.

On the other hand, the second sub-compensation circuit SA2 further includes a third compensation component S23 that is connected between the non-inverting input terminal of the second amplifier AMP2 and is connected to a node to which the first terminal of the first compensation component S21 and the first terminal of the compensation switch SWp2 are connected.

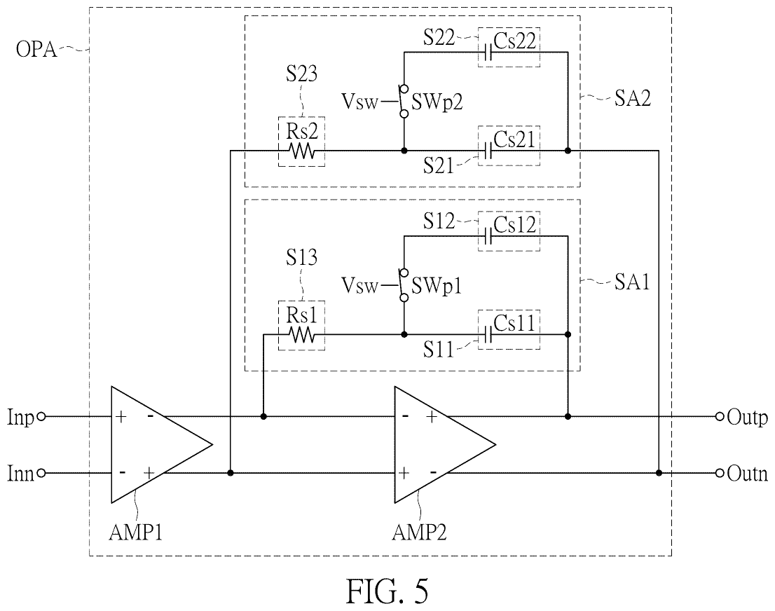

Reference is made to FIG. 5 and FIG. 6, in which FIG. 5 is a circuit diagram of a two-stage operational amplifier according to the fifth embodiment of the present disclosure, and the descriptions of the fifth embodiment that are the same as the descriptions of the fourth embodiment are not repeated herein.

The compensation circuit SAT shown in FIG. 1 may include the first sub-compensation circuit SA1 and the second sub-compensation circuit SA2 shown in FIG. 2 and FIG. 3 may be the same as the second sub-compensation circuit SA2.

As shown in FIG. 5, the first compensation component S11 and the second compensation component S12 of the first sub-compensation circuit SA1 may respectively include capacitors Cs11, Cs12 and the first compensation component S21 and the second compensation component S22 of the second sub-compensation circuit SA2 may respectively include capacitors Cs21, Cs22. The third compensation components S13, S23 of the first sub-compensation circuit SA1 and the second sub-compensation circuit SA2 may include resistors Rs1, Rs2. Thus, the resistors Rs1, Rs2 of the third compensation components S13, S23 can be avoid a short-circuit state of the input/output terminals of the second amplifier AMP2 in a higher frequency range. Furthermore, phase margin of the two-stage operational amplifier OPA can be adjusted by combination of the resistors Rs1, Rs2 and the capacitors Cs21, Cs22, Cs11, Cs12 via the compensation switches SWp1, SWp2.

The capacitor Cs11 is used as a first capacitor, the capacitor Cs12 is used as a second capacitor, the capacitor Cs21 is used as a third capacitor, and the capacitor Cs22 is used as a fourth capacitor. The resistor Rs1 is used as a first resistor, and the resistor Rs2 is used as a second resistor. The compensation switch SWp1 is used as a first compensation switch, and the compensation switch SWp2 is used as a second compensation switch.

When the load switch SWd shown in FIG. 6 is turned on, the inverting input terminal of the current integrator 1000 is connected to the photodiode PD through the load switch SWd in the optical sensor 2000 shown in FIG. 6, the compensation switch SWp1 and the compensation switch SWp2 shown in FIG. 3 are turned off by the variable control voltage Vsw at the initial voltage level such as the low level.

The compensation switches SWp1, SWp2 are synchronously turned off or on. When the compensation switches SWp1, SWp2 are synchronously turned off, the voltage between the inverting input terminal and the positive output terminal of the second amplifier AMP2 is compensated based on the first compensation value that only includes a resistance of the resistor Rs1 and a first capacitance of the capacitor Cs11, and the voltage between the non-inverting input terminal and the negative output terminal of the second amplifier AMP2 is compensated based on the first compensation value that only includes a resistance of the resistor Rs2 and the first capacitance of the capacitor Cs21.

It is worth noting that, when the load switch SWd is turned off, the inverting input terminal of the current integrator 1000 is unconnected to the photodiode PD through the load switch SWd in the optical sensor 2000 shown in FIG. 6, the compensation switch SWp1 and the compensation switch SWp2 shown in FIG. 3 are turned on by the variable control voltage Vsw at the first voltage level such as the high level.

When the compensation switches SWp1, SWp2 are synchronously turned on, the voltage between the inverting input terminal and the positive output terminal of the second amplifier AMP2 is compensated based on the second compensation value that includes a total capacitance and the resistance of the resistor Rs1, wherein the total capacitance is a sum of the first capacitance of the capacitor Cs11 and a second capacitance of the second capacitor Cs12. At the same time, the voltage between the non-inverting input terminal and the negative output terminal of the second amplifier AMP2 is compensated based on the second compensation value that includes a total capacitance and the resistance of the resistor Rs2. The total capacitance is a sum of the first capacitance of the capacitor Cs21 and a second capacitance of the second capacitor Cs22.

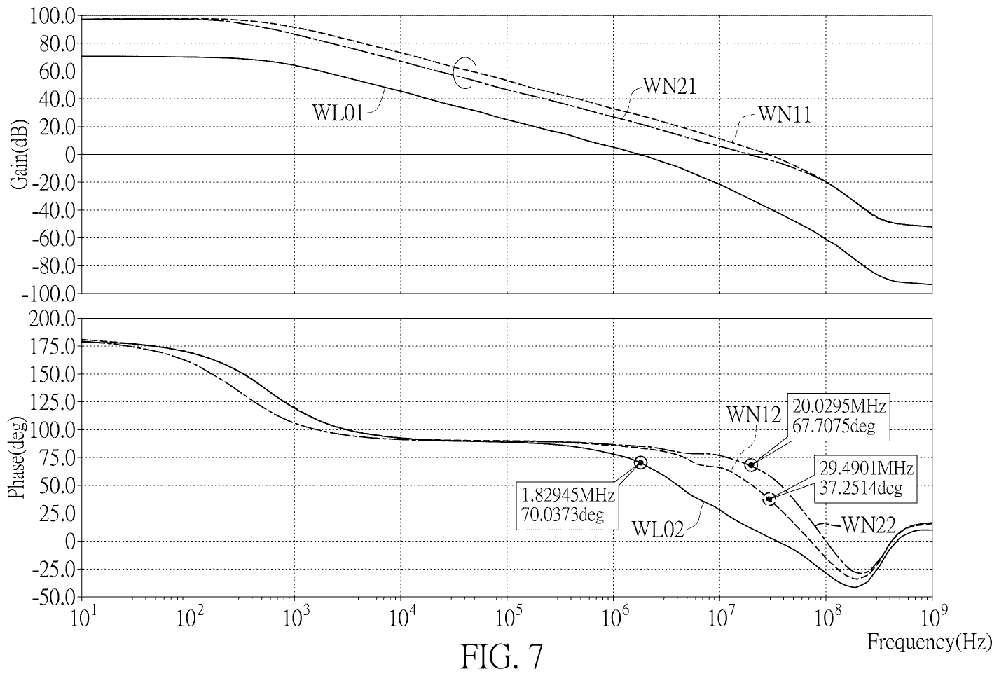

Reference is made to FIG. 7, which is a waveform diagram of signals of the two-stage operational amplifier of the first to fifth embodiments and a conventional operational amplifier.

A difference between the conventional operational amplifier and the present disclosure is that, the first amplifier AMP1, the second amplifier AMP2 and the compensation circuit SAT are disposed inside the two-stage operational amplifier OPA as shown in FIG. 1 to FIG. 5, rather than being disposed inside the conventional operational amplifier.

When a load such as a photodiode is connected to the conventional operational amplifier through a load switch, a gain-frequency curve WL01 and a phase-frequency curve WL02 of the conventional operational amplifier may be the same as a curve WL01 or WL02 shown in FIG. 7.

When the current integrator 1000 is connected to the load circuit LD shown in FIG. 6 through the load switch SWd being turned on, a gain-frequency curve WL01 and a phase-frequency curve WL02 of the current integrator 1000 are as shown in FIG. 7. As marked on the curve phase- frequency WL02, the two-stage operational amplifier has 70deg phase margin and 1.83 MHz bandwidth in PD load condition.

Conversely, when the load is removed from the conventional operational amplifier, a gain-frequency curve WN11 and a phase-frequency curve WN12 of the conventional operational amplifier unstably change, which is caused by a parasitic capacitance of the load such as the photodiode. As marked on the phase-frequency curve WL12, the conventional operational amplifier has 37deg of a phase at 29.5 MHz of a frequency. As a result, the conventional operational amplifier performs a less stable operation in time domain, which results in high ringing and even uncontrollable oscillation.

In contrast, when the load switch SWd is turned off such that the load circuit LD is unconnected to the current integrator 1000 or the load switch SWd is removed from the current integrator 1000, a gain-frequency curve WN21 and a phase-frequency curve WN22 of the current integrator 1000 more stably changes than the gain-frequency curve WN11 and the phase-frequency WN12 of the conventional operational amplifier as shown in FIG. 7. As marked on the phase-frequency curve WL22, the current integrator 1000 has 67.7075deg of a phase at 20.0295 MHz of a frequency.

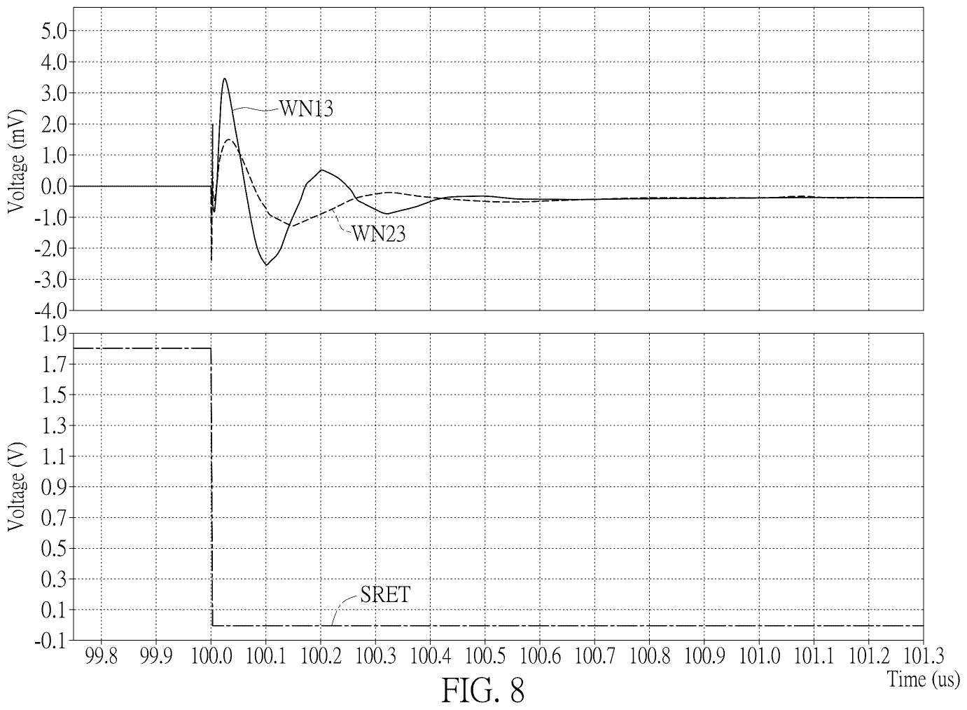

Reference is made to FIG. 8, which is a waveform diagram of signals of the two-stage operational amplifier according to the first to fifth embodiments.

As shown in FIG. 8, when a rest signal SRET is at a high level, a voltage WN23 of the inverting input terminal of the current integrator 1000 is reset to a zero value.

After the voltage of the inverting input terminal of the current integrator 1000 as shown in FIG. 6 is reset to the zero value shown in FIG. 8, the load switch SWd shown in FIG. 6 is turned off. As a result, the inverting input terminal of the current integrator 1000 is unconnected to the load circuit LD through the load switch SWd. At this time, the voltage WN23 of the current integrator 1000 more stably changes than that of a voltage WN23 of the conventional operational amplifier.

In conclusion, the present disclosure provides the two-stage operational amplifier. The two-stage operational amplifier includes the first amplifier, the second amplifier and the compensation circuit. When the two-stage operational amplifier is connected to the load, the compensation circuit compensates the voltage that is amplified by the first amplifier and received by the second amplifier based on the first compensation value. Under this condition, the two-stage operational amplifier is capable of outputting stable voltages at high speed. Then, when the two-stage operational amplifier is unconnected to the load, the compensation circuit compensates the voltage that is amplified by the first amplifier and received by the second amplifier based on the second compensation value being larger than the first compensation value. Under this condition, the two-stage operational amplifier is capable of continually outputting the stable voltages.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A two-stage operational amplifier, comprising:
a first amplifier, wherein a plurality of input terminals of the first amplifier are respectively coupled to a plurality of input voltages;
a second amplifier, wherein a plurality of input terminals of the second amplifier are respectively connected to a plurality of output terminals of the first amplifier; and
a compensation circuit connected to the plurality of input terminals of the second amplifier;
wherein, when the input voltage received by one of the plurality of input terminals of the first amplifier is outputted from a load, the compensation circuit compensates a first voltage received by the compensation circuit to form a first compensation voltage based on a first compensation value;
wherein, when the input voltage received by one of the plurality of input terminals of the first amplifier is not outputted from the load, the compensation circuit compensates a second voltage received by the compensation circuit to form a second compensation voltage based on a second compensation value.

2. An optical sensor, comprising:
a current integrator including the two-stage operational amplifier according to claim 1, a first integrating capacitor and a second integrating capacitor; and
a load switch; and
a load;
wherein the load switch is connected between the load and the two- stage operational amplifier;
wherein the first integrating capacitor, the second integrating capacitor and the two-stage operational amplifier are connected in parallel.

3. The two-stage operational amplifier according to claim 1, wherein the compensation circuit includes a plurality of sub-compensation circuits each having a first terminal and a second terminal, the first terminals of the plurality of sub-compensation circuits are respectively connected to the plurality of input terminals of the second amplifier, and the second terminals of the plurality of sub-compensation circuits are respectively connected to a plurality of output terminals of the second amplifier.

4. The two-stage operational amplifier according to claim 3, wherein the plurality of sub-compensation circuits includes:
a first sub-compensation circuit, wherein an input terminal of the first sub-compensation circuit is connected to a first input terminal included in the plurality of input terminals of the second amplifier, and an output terminal of the first sub-compensation circuit is connected to a first output terminal included in the plurality of output terminals of the second amplifier; and
a second sub-compensation circuit, wherein an input terminal of the second sub-compensation circuit is connected to a second input terminal included in the plurality of input terminals of the second amplifier, and an output terminal of the second sub-compensation circuit is connected to a second output terminal included in the plurality of output terminals of the second amplifier.

5. The two-stage operational amplifier according to claim 4, wherein the first sub-compensation circuit includes:
a compensation switch, wherein a first terminal of the compensation switch is connected to the first input terminal of the second amplifier, and a control terminal of the compensation switch is coupled to a variable control voltage;
a first compensation component, wherein a first terminal of the first compensation component is connected to the first input terminal of the second amplifier, and a second terminal of the first compensation component is connected to the first output terminal of the second amplifier; and
a second compensation component, wherein a first terminal of the second compensation component is connected to a second terminal of the compensation switch, and a second terminal of the second compensation component is connected to the first output terminal of the second amplifier.

6. The two-stage operational amplifier according to claim 5, wherein, when any one of the plurality of input terminals of the first amplifier is connected to a load, the compensation switch is turned off;
wherein, when each of the plurality of input terminals of the first amplifier is unconnected to the load, the compensation switch is turned on.

7. The two-stage operational amplifier according to claim 5, wherein the first compensation component includes a capacitor and the second compensation component includes a capacitor.

8. The two-stage operational amplifier according to claim 5, wherein the first sub-compensation circuit further includes:
a third compensation component, wherein the third compensation component is connected between the first input terminal of the second amplifier and the first terminal of the first compensation component.

9. The two-stage operational amplifier according to claim 8, wherein the third compensation component is connected between the first input terminal of the second amplifier and the first terminal of the compensation switch.

10. The two-stage operational amplifier according to claim 8, wherein the third compensation component includes a resistor.

11. The two-stage operational amplifier according to claim 4, wherein the second sub-compensation circuit includes:
a compensation switch, wherein a first terminal of the compensation switch is connected to the second input terminal of the second amplifier, and a control terminal of the compensation switch is coupled to a variable control voltage;
a first compensation component, wherein a first terminal of the first compensation component is connected to the second input terminal of the second amplifier, and a second terminal of the first compensation component is connected to the second output terminal of the second amplifier; and
a second compensation component, wherein a first terminal of the second compensation component is connected to a second terminal of the compensation switch, and a second terminal of the second compensation component is connected to the second output terminal of the second amplifier.

12. The two-stage operational amplifier according to claim 11, wherein the first compensation component includes a capacitor and the second compensation component includes a capacitor.

13. The two-stage operational amplifier according to claim 11, wherein the second sub-compensation circuit further includes:
a third compensation component, wherein the third compensation component is connected between the second input terminal of the second amplifier and the first terminal of the first compensation component.

14. The two-stage operational amplifier according to claim 13, wherein the third compensation component is connected between the second input terminal of the second amplifier and the first terminal of the compensation switch.

15. The two-stage operational amplifier according to claim 13, wherein the third compensation component includes a resistor.

16. An optical sensor, comprising:
a current integrator including:
a two-stage operational amplifier including:
a first amplifier, wherein a plurality of input terminals of the first amplifier are respectively coupled to a plurality of input voltages;
a second amplifier, wherein a plurality of input terminals of the second amplifier are respectively connected to a plurality of output terminals of the first amplifier; and
a compensation circuit connected to the plurality of input terminals of the second amplifier;
a photodiode, wherein an anode of the photodiode is grounded; and
a load switch connected between a cathode of the photodiode and one of the plurality of input terminals of the first amplifier;
wherein, when the input voltage received by the one of the plurality of input terminals of the first amplifier is outputted from a load, the compensation circuit compensates a first voltage received by the compensation circuit to form a first compensation voltage based on a first compensation value;
wherein, when the input voltage received by the one of the plurality of input terminals of the first amplifier is not outputted from the load, the compensation circuit compensates a second voltage received by the compensation circuit to form a second compensation voltage based on a second compensation value.

17. The optical sensor according to claim 16, wherein the current integrator further includes:
a first integrating capacitor connected between a first input terminal and a first output terminal of the two-stage operational amplifier; and
a second integrating capacitor connected between a second input terminal and a second output terminal of the two-stage operational amplifier.

18. The optical sensor according to claim 16, wherein the compensation circuit includes:
a first capacitor connected between the first input terminal of the second amplifier and the first output terminal of the second amplifier;
a second capacitor connected to the first capacitor in parallel;
a third capacitor connected between the second input terminal of the second amplifier and the second output terminal of the second amplifier;
a fourth capacitor connected to the third capacitor in parallel;
a first compensation switch connected between the first capacitor and the second capacitor;
a second compensation switch connected between the third capacitor and the fourth capacitor; and
wherein a control terminal of the first compensation switch and a control terminal of the second compensation switch are coupled to a variable control voltage.

19. The optical sensor according to claim 18, wherein, when the input voltage received by the one of the plurality of input terminals of the first amplifier is outputted from the load, the two compensation switches are turned off;
wherein, when the input voltage received by the one of the plurality of input terminals of the first amplifier is not outputted from the load, the two compensation switches are turned on.

20. The optical sensor according to claim 18, wherein the compensation circuit further includes:
a first resistor connected to the first input terminal of the second amplifier and a node between the first capacitor and the first compensation switch; and
a second resistor connected to the second input terminal of the second amplifier and a node between the third capacitor and the second compensation switch.
